(19) United States
(12) Patent Application Publication
(10) Pub. No.: US 2021/0359070 A1
(43) Pub. Date: Nov. 18, 2021

(54) DISPLAY DEVICE

(71) Applicant: Wuhan China Star Optoelectronics Semiconductor Display Technology Go., Ltd., Wuhan (CN)

(72) Inventor: Jiangjiang JIN, Wuhan (CN)

(21) Appl. No.: 16/481,070

(22) PCT Filed: Mar. 14, 2019
(86) PCT No.: PCT/CN2019/078071

§ 371 Date: Jul. 26, 2019

(30) Foreign Application Priority Data
Dec. 6, 2018 (CN) 201811486970.1

(51) Int. Cl. H01L 27/32

(52) U.S. Cl. CPC H01L 27/3276; H01L 51/0097

(57) ABSTRACT

A display panel is provided and advantages thereof are that a metal wiring of a bending area is provided with protrusions that extend in a second direction. The design of the protruded metal wiring can effectively reduce a risk of cracking and prevent a longitudinal extension of a crack.

### FIELD OF INVENTION

The present disclosure relates to a field of display devices, and more particular to a display panel.

### BACKGROUND OF INVENTION

Organic light emitting diodes (OLEDs) possess many outstanding properties, such as fast response times, being self-illuminous, high contrast, and have a wide range of working temperatures, etc. Compared to other display technologies, the biggest feature of OLEDs is its ability to achieve flexible displays. Flexible displays have higher requirements on manufacturing processes of components and materials. Nowadays, all-screen mobile phones are increasingly favored by consumers, and OLED flexible display technology can bend components of a non-display portion to make a display portion relatively enlarged, thereby increasing the screen ratio of a display device. However, the requirements for devices used for bending is higher, and films are prone to cracking in a long period of dynamic or static bending. Therefore, how to effectively avoid the cracking of films is a current primary task.

### Technical Problems

U.S. Pat. No. 9,287,342 discloses a flexible OLED display structure, the components are divided into three areas, a display area (DA), a non-display area (NDA), and a bending area (BA). This flexible display device has higher requirement for the flexibility of the bending area. The bending areas of the patent include a flexible substrate, a buffer layer, a conductive layer, and a passivation layer disposed on the conductive layer. If such a display device is statically bent or dynamically bent at the bending area for a long period of time, the bending area may crack due to the continuity of the buffer layer.

U.S. Pat. No. 9,318,427 discloses a flexible OLED display structure. Metal wirings of a bending area of a display structure are stepped, which can theoretically increase the bending ability. However, a buffer layer which is disposed under a metal conductive layer employs a continuous inorganic film so that the inorganic film is prone to cracking and diffuse toward the metal layer during bending.

U.S. Pat. No. 9,706,607 discloses a flexible OLED display device in details. The display device is divided into an active area, a secondary active area, and a wiring layer. The active area and the secondary active area are connected together by a wire layer. Structures of the wire layer are, in a bottom-to-top order, a substrate, a buffer layer composed of an inorganic material, such as SiOₓ or SiN, a metal wiring for conducting the active area and the secondary active area. The SiOₓ or SiN inorganic layer is disposed on the metal wiring. The inorganic layer, which is below and above the metal wiring, can block external water oxygen and protect the metal wiring. However, these continuous inorganic film layers are less flexible and prone to cracking during bending. The cracks will extend into the metal wire, thereby causing the metal wiring to crack.

U.S. Patent Application No. US20170315399 discloses a flexible OLED display device. The display device is divided into a display area and a bending area. The bending area is, in a top-to-bottom order, a flexible substrate, a source and drain (SD) metal wire, a metal wire, and an insulating layer. The insulating layer also has the risk of cracking during bending.

### SUMMARY OF INVENTION

The technical problems solved by the present disclosure is to provide a display panel which can effectively reduce the risk of cracking and prevent longitudinal extension of cracks.

In order to solve the above technical problems, the present disclosure provides a display panel comprising: a display area and a bending area, wherein the bending area is bendable with respect to the display area, at least one metal wiring is disposed on the bending area, the metal wiring extends in a first direction, at least one side of the metal wiring comprises at least one protrusion, the protrusion extends in a second direction, a plurality of via holes are defined on the metal wiring, the via holes are arranged in the first direction, and the via holes are defined corresponding to the protrusions, and the first direction is perpendicular to the second direction on a plane where the metal wiring is located.

In an embodiment, two sides of the metal wiring both comprise the at least one protrusion.

In an embodiment, two sides of the metal wiring both comprise a plurality of the protrusions and the protrusions are alternately arranged in the first direction.

In an embodiment, two sides of the metal wiring both comprise a plurality of the protrusions and the protrusions are symmetrically arranged in the first direction.

In an embodiment, shapes of the via holes are selected from circles and ovals.

In an embodiment, shapes of the protrusions are selected from arcs and triangles.

In an embodiment, in the bending area, the display panel further comprises a substrate and a functional layer disposed on the substrate, the functional layer comprises a via hole and a filling layer filling the via holes, and the metal wiring is positioned on the filling layer.

In an embodiment, the substrate and the functional layer are extended to the display area, and in the display area, the display panel further comprises a flat layer disposed on the functional layer, a light emitting layer disposed on the flat layer, and an encapsulation layer disposed on the light emitting layer.

In order to solve the above problems, the present disclosure further provides a display panel comprising: a display area and a bending area, wherein the bending area is bendable with respect to the display area, at least one metal wiring is disposed on the bending area, the metal wiring extends in a first direction, at least one side of the metal wiring comprises at least one protrusion, the protrusion extends in a second direction, and the first direction is perpendicular to the second direction on a plane where the metal wiring is located.

In an embodiment, two sides of the metal wiring both comprise the at least one protrusion.

In an embodiment, two sides of the metal wiring both comprise a plurality of the protrusions and the protrusions are alternately arranged in the first direction.

In an embodiment, two sides of the metal wiring both comprise a plurality of the protrusions and the protrusions are symmetrically arranged in the first direction.

In an embodiment, a plurality of via holes are defined on the metal wiring, the via holes are arranged in the first direction.

In an embodiment, the via holes are defined corresponding to the protrusions.

In an embodiment, shapes of the via holes are selected from circles and ovals.

In an embodiment, shapes of the protrusions are selected from arcs and triangles.

In an embodiment, in the bending area, the display panel further comprises a substrate and a functional layer disposed on the substrate, the functional layer comprises a via hole and a filling layer filling the via holes, and the metal wiring is positioned on the filling layer.

In an embodiment, the substrate and the functional layer are extended to the display area, and in the display area, the display panel further comprises a flat layer disposed on the functional layer, a light emitting layer disposed on the flat layer, and an encapsulation layer disposed on the light emitting layer.

### Beneficial Effects

The beneficial effects of the present disclosure are that a crack easily extends in a direction perpendicular to the metal wiring in the bending area during the bending of the display panel. The metal wiring of the display panel of the present disclosure is provided with a protrusion extending in the second direction. The design of the protruded metal wiring can effectively reduce a risk of cracking and prevent a longitudinal extension of a crack.

### DESCRIPTION OF DRAWINGS

FIG. 1 is a top structural schematic view of a display panel of a first embodiment of the present disclosure;

FIG. 2 is a side structural schematic view of the display panel of the first embodiment of the present disclosure;

FIG. 3 is a top structural schematic view of the display panel of a second embodiment of the present disclosure;

FIG. 4 is a top structural schematic view of the display panel of a third embodiment of the present disclosure; and

FIG. 5 is a top structural schematic view of the display panel of a fourth embodiment of the present disclosure.

### DETAILED DESCRIPTION OF PREFERRED EMBODIMENTS

Specific embodiments of display panels of the present disclosure will be further described in detail with the accompanying drawings.

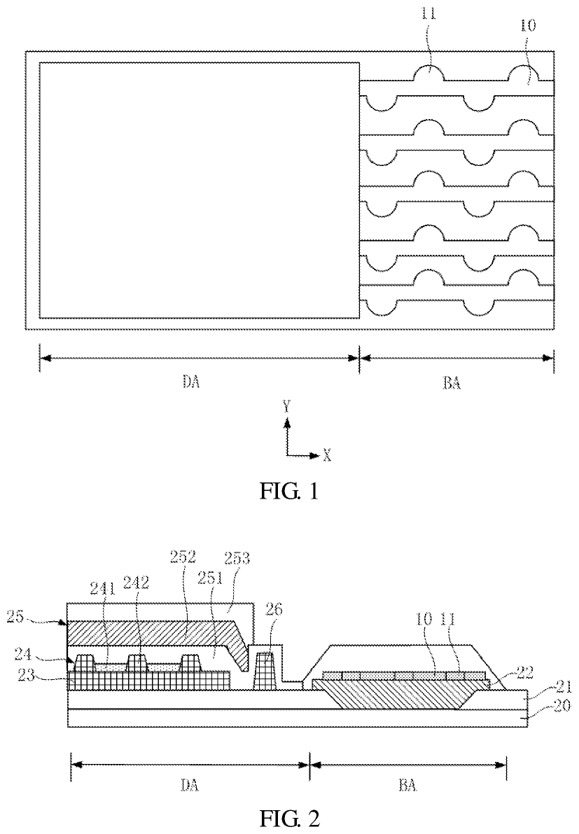

FIG. 1 is a top structural schematic view of a display panel of a first embodiment of the present disclosure and FIG. 2 is a side structural schematic view of the display panel of the first embodiment of the present disclosure. Please refer to FIG. 1 and FIG. 2, the display panel of the present disclosure comprises a display area DA and a bending area BA.

The display area DA refers to an area that serves as a display screen of the display panel. The bending area BA refers to an area that can be bent, wherein the bending area BA is bent relative to the display area DA. Specifically, the bending area BA is bent toward a back surface of the display area DA. The back side of the display area DA refers to a side on which the display panel does not need to be displayed. In the present embodiment, the bending area BA is disposed at a lower bezel of the display area DA. Therefore, the bending area BA can be bent toward the back of the display area DA at a lower edge of the display area DA.

In the embodiment, in the bending area BA, the display panel further comprises a substrate 20 and a functional layer 21 disposed on the substrate 20. The functional layer 21 comprises a via hole (not shown in the drawing). A filling layer 22 fills the via hole. In particular, the substrate 20 can be a flexible substrate that can be made of a flexible material which is well known to those skilled in the art. The functional layer 21 includes but not limited to various inorganic insulating layers of thin film transistors. The filling layer 22 includes but is not limited to an organic material layer. The substrate 20 and the functional layer 21 each extend to the display area DA.

In the display area DA, the functional layer 21 further includes other material layers necessary for forming a thin film transistor, and details are not described herein again. In the display area DA, the display panel further comprises a flat layer 23 disposed on the functional layer 21, a light emitting layer 24 disposed on the flat layer 23, and an encapsulation layer 25 disposed on the light emitting layer 24. Specifically, in the present embodiment, the display panel is an organic light emitting display panel, and the structure of the display area DA can be obtained by those skilled in the art from the prior art. For example, the light emitting layer 24 comprises an organic layer 241 and a pixel defining layer 242. The organic layer 241 is surrounded by the pixel defining layer 242. The encapsulating layer 25 comprises a first inorganic layer 251 in contact with the light emitting layer 24, an organic encapsulation layer 252 disposed on the first inorganic encapsulation layer 251, and a second inorganic encapsulation layer 253 on the organic encapsulation layer 252. A blocking wall 26 is disposed at an edge of the display area DA.

At least one metal wiring 10 is disposed in the bending area BA. The metal wiring 10 is used for connecting a metal wire of the thin film transistor of the display area DA with an integrated circuit (not shown in the drawing) located on the other side of the bending area BA. In the present embodiment, in order to reduce the bending stress, the metal wiring 10 is located on the filling layer 22. The number of metal wirings 10 is not limited herein. In the present embodiment, only five metal wirings 10 are schematically illustrated. The metal wirings 10 may be arranged in parallel.

The metal wiring 10 extends in a first direction. Specifically, the metal wiring 10 extends from one end of the bending area BA to the other end of the bending area BA and the metal wiring 10 is connected to an integrated circuit located at the other end of the bending area BA. In the present embodiment, the first direction is set to an x-direction.

At least one side of the metal wiring 10 comprises at least one protrusion 11. The protrusion 11 extends in a second direction. The first direction is perpendicular to the second direction on a plane where the metal wiring 10 are located. In the embodiment, the second direction is set to a y-direction. Specifically, the protrusions 11 are provided on one side or both sides of the metal wiring 10. The protrusions 11 extend in a direction of a width of the metal wiring 10, rather than a direction of a height of the metal wiring 10. For example, in the present embodiment, two sides of the metal wiring 10 both comprise a plurality of the protrusions 11 extending in the second direction. In the first direction, the protrusions 11 are alternately arranged, i.e., the protrusions 11 on one side of the metal wiring 10 and the protrusions 11 on the other side are alternately arranged.

Shapes and sizes of the protrusions 11 can be adaptively changed according to the structure of the display panel. Specifically, the shape of the protrusion 11 includes but is not limited to an arc or a triangle, such as a semicircle, an oval, a cone, etc.

During the bending of the display panel, in the bending area BA, a crack easily extends in a direction perpendicular to the metal wiring 10, i.e., the crack easily extends in the second direction during the bending of the display panel. Therefore, the metal wiring 10 of the display panel of the present disclosure is provided with a protrusion extending in the second direction. The design of the protruded metal wiring can effectively reduce a risk of cracking and prevent a longitudinal extension of a crack.

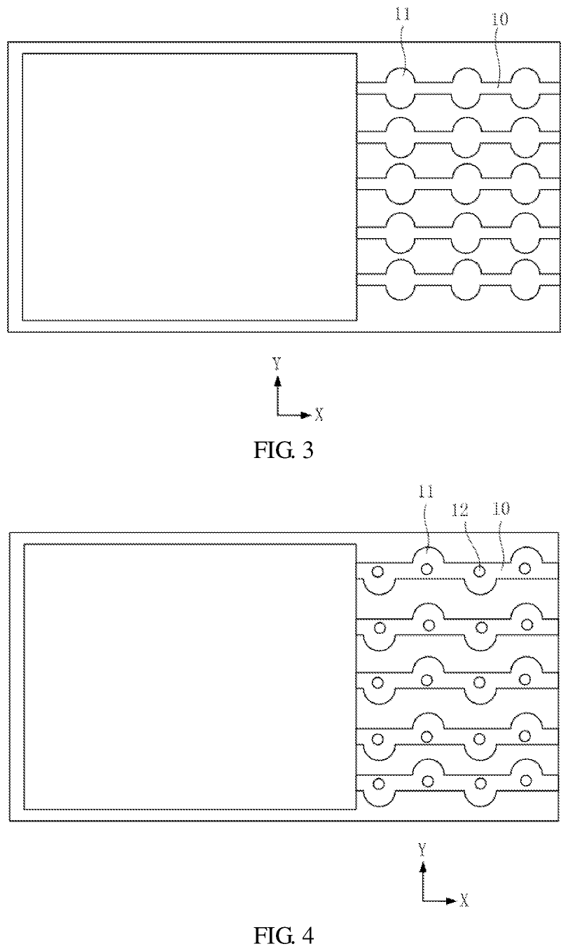

FIG. 3 is a top structural schematic view of the display panel of a second embodiment of the present disclosure. Please refer to FIG. 3, the difference between the second embodiment and the first embodiment is that the arrangements of the protrusions 11 are different. In the present embodiment, two sides of the metal wiring 10 both comprise a plurality of the protrusions 11 and the protrusions 11 are symmetrically arranged in the first direction. In the present embodiment, the first direction is set to the x-direction, and the second direction is the y-direction. Specifically, the protrusions 11 of one side of the metal wiring 10 and the protrusions 11 of the other side of the metal wiring 10 are axisymmetrically distributed in a center line. The center line is a center line of the metal wiring 10.

FIG. 4 is a top structural schematic view of the display panel of a third embodiment of the present disclosure. Please refer to FIG. 4, the difference between the third embodiment and the first embodiment is that a plurality of via holes 12 are defined on the metal wiring 10. Specifically, in the third embodiment, a plurality of via holes 12 are defined on the metal wiring 10. The via holes 12 are arranged in the first direction, i.e., the via holes 12 are arranged in a direction in which the metal wiring 10 is extended. In the present embodiment, the via holes 12 are defined corresponding to the protrusions 11, i.e., in the case of a plurality of protrusions on two sides of the metal wiring are alternately arranged, one of the protrusions 11 corresponds to one of the via holes 12. The via holes 12 can alleviate stresses received by the metal wiring 10, thereby further reducing the risk of cracking. Shapes of the via holes 12 are circles or ovals. In other embodiments, shapes of the via holes 12 can also be changed by a person skilled in the art according to requirements.

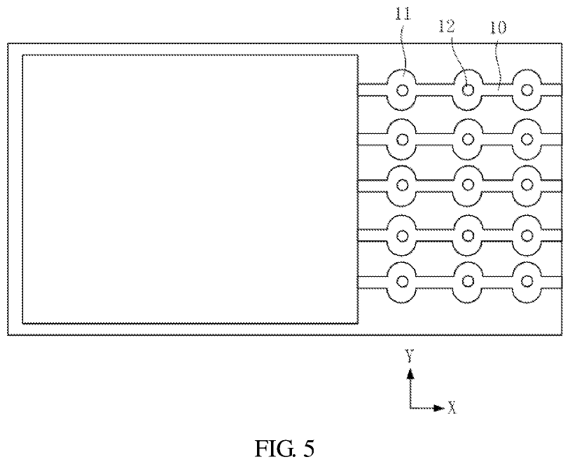

FIG. 5 is a top structural schematic view of the display panel of a fourth embodiment of the present disclosure. Please refer to FIG. 5, the differences between the fourth embodiment and the first embodiment are that the arrangements of the via holes 12 and the protrusions 11 on the metal wiring 10 are different. Specifically, in the fourth embodiment, a plurality of via holes 12 are defined on the metal wiring 10, and the via holes 12 are arranged in a first direction, that is, the via holes 12 in the metal wirings 10 are arranged in the direction in which they extend. A plurality of protrusions 11 are disposed on both sides of the metal wiring 10, and the protrusions 11 are symmetrically arranged in the first direction. In the present embodiment, the first direction is set to the X direction, and the second direction is the Y direction. Specifically, the protrusions 11 on one side of the metal wiring 10 and the protrusions 11 on the other side of the metal wiring 10 are symmetrically distributed in a center line. The center line is a center line of the metal wiring 10. In the present embodiment, the via holes 12 are defined corresponding to the protrusions 11, i.e., two symmetric protrusions 11 are disposed corresponding to one of the via holes 12.

The above are merely the preferred embodiments of the present disclosure. It should be appreciated that a person skilled in the art may further make modifications and improvements without departing from the principle of the present disclosure, and these modifications and improvements shall also fall within the scope of the present disclosure.

### INDUSTRIAL APPLICABILITY

The subject matter of the present application can be manufactured and used in the industry. Therefore, the present application possesses industrial applicability.

1. A display panel, comprising: a display area and a bending area, wherein the bending area is bendable with respect to the display area, at least one metal wiring is disposed on the bending area, the metal wiring extends in a first direction, at least one side of the metal wiring comprises at least one protrusion, the protrusion extends in a second direction, and a plurality of via holes are defined on the metal wiring, the via holes are arranged in the first direction, and the via holes are defined corresponding to the protrusions, and the first direction is perpendicular to the second direction on a plane where the metal wiring is located.

2. The display panel according to claim 1, wherein two sides of the metal wiring both comprise the at least one protrusion.

3. The display panel according to claim 1, wherein two sides of the metal wiring both comprise a plurality of the protrusions and the protrusions are alternately arranged in the first direction.

4. The display panel according to claim 1, wherein two sides of the metal wiring both comprise a plurality of the protrusions and the protrusions are symmetrically arranged in the first direction.

5. The display panel according to claim 1, wherein shapes of the via holes are selected from circles and ovals.

6. The display panel according to claim 1, wherein shapes of the protrusions are selected from arcs and triangles.

7. The display panel according to claim 1, wherein in the bending area, the display panel further comprises a substrate and a functional layer disposed on the substrate, the functional layer comprises a via hole, a filling layer filling the via holes, and the metal wiring is positioned on the filling layer.

8. The display panel according to claim 7, wherein the substrate and the functional layer are extended to the display area, and in the display area, the display panel further comprises a flat layer disposed on the functional layer, a light emitting layer disposed on the flat layer, and an encapsulation layer disposed on the light emitting layer.

9. A display panel, comprising: a display area and a bending area, wherein the bending area is bendable with respect to the display area, at least one metal wiring is disposed on the bending area, the metal wiring extends in a first direction, at least one side of the metal wiring comprises at least one protrusion, the protrusion extends in a second direction, and the first direction is perpendicular to the second direction on a plane where the metal wiring is located.

10. The display panel according to claim 9, wherein two sides of the metal wiring both comprise the at least one protrusion.

11. The display panel according to claim 9, wherein two sides of the metal wiring both comprise a plurality of the protrusions and the protrusions are alternately arranged in the first direction.

12. The display panel according to claim 9, wherein two sides of the metal wiring both comprise a plurality of the protrusions and the protrusions are symmetrically arranged in the first direction.

13. The display panel according to claim 9, wherein a plurality of via holes are defined on the metal wiring, the via holes are arranged in the first direction.

14. The display panel according to claim 13, wherein the via holes are defined corresponding to the protrusions.

15. The display panel according to claim 13, wherein shapes of the via holes are selected from circles and ovals.

16. The display panel according to claim 9, wherein shapes of the protrusions are selected from arcs and triangles.

17. The display panel according to claim 9, in the bending area, the display panel further comprises a substrate and a functional layer disposed on the substrate, the functional layer comprises a via hole, a filling layer filling the via holes, and the metal wiring is positioned on the filling layer

18. The display panel according to claim 17, wherein the substrate and the functional layer are extended to the display area, and in the display area, the display panel further comprises a flat layer disposed on the functional layer, a light emitting layer disposed on the flat layer, and an encapsulation layer disposed on the light emitting layer.
